(19) United States
(12) Patent Application Publication
(10) Pub. No.: US 2008/0088543 A1
(43) Pub. Date: Apr. 17, 2008

(54) Display, Array Substrate, and Display Manufacturing Method

(76) Inventor: Makoto Shibusawa, Fukaya-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/658,044

(22) PCT Filed: Jan. 19, 2005
(86) PCT No.: PCT/JP05/00943

§ 371 Date: Jan. 22, 2007

(30) Foreign Application Priority Data
Sep. 14, 2004 (JP) 2004-267020

(51) Int. Cl. G09G 3/30; G09G 3/20; H01L 21/26

(52) U.S. Cl. 345/76; 345/55; 438/29; 257/E21.535

(57) ABSTRACT

Provided is a display including pixels (PX) arrayed in a matrix form and video signal lines (DL) arranged correspondently with columns which the pixels (PX) form, wherein each pixel (PX) includes a display element (OLED) and a pixel circuit including a drive transistor (DR) whose source is connected to a first power supply terminal (ND1) and whose drain is connected to the display element (OLED), and wherein a periodic variation in a property of the drive transistor (DR) appears in a row which the pixels (PX) form.

### TECHNICAL FIELD

The present invention relates to a display, an array substrate, and a display manufacturing method.

### BACKGROUND ART

An organic EL (electroluminescent) display is one of displays which control optical behaviors of a display element by a drive current flowing therethrough. In such displays, if the drive current varies, the image quality becomes poor due to, e.g., luminance unevenness. Therefore, in the case where such a display uses an active matrix driving method, it is required that drive control elements of pixels which control a magnitude of the drive current have substantially uniform properties. However, in this display, in general, the drive control elements are formed on an insulator such as a glass substrate, and thus, their properties readily vary.

In U.S. Pat. No. 6,373,454B1, there is described an organic EL display using a current copy type circuit as a pixel circuit.

The current copy type pixel circuit includes an n-channel FET (field-effect transistor) as a drive control element, an organic EL element and a capacitor. A source of the n-channel FET is connected to a power supply line which is set at a lower electric potential, and the capacitor is connected between a gate of the n-channel FET and the power supply line. In addition, an anode of the organic EL element is connected to a power supply line which is set at a higher electric potential.

The pixel circuit is driven in accordance with the following method.

First, drain and gate of the n-channel FET are connected to each other. In this state, a current Isig whose magnitude corresponds to a video signal is made flow between the drain and source of the n-channel FET. With this operation, the voltage between the two electrodes of the capacitor becomes the gate to source voltage necessary for the current Isig to flow through the channel of the n-channel FET.

Next, the drain and gate of the n-channel FET are disconnected from each other, and the voltage between both electrodes of the capacitor is maintained. Then, the drain of the n-channel FET is connected to a cathode of the organic EL element. In this manner, a drive current whose magnitude is substantially equal to that of the current Isig flows through the organic EL element. The organic EL element emits light at a luminance which corresponds to the magnitude of this drive current.

As described above, by using the current copy type circuit for a pixel circuit, the drive current with a magnitude substantially equal to that of the current Isig, which is made flow as a video signal during the write period, can flow between the drain and the source of the n-channel FET during the holding period next to the write period. For this reason, not only the influence of the threshold value Vth of the n-channel FET but also the influence of its mobility and dimensions on the drive current can be eliminated.

However, the present inventor has found out that, when an image is displayed on a display which uses the current copy type circuit as a pixel circuit, streaks which are parallel to scan signal lines and arranged at regular intervals in a direction along video signal lines may appear on the image.

### DISCLOSURE OF INVENTION

An object of the present invention is to prevent the display unevenness from occurring.

According to a first aspect of the present invention, there is provided a display comprising a substrate, pixels arrayed in a matrix form over the substrate, and video signal lines arranged correspondently with columns which the pixels form, wherein each of the pixels comprises a display element arranged between first and second power supply terminals, and a pixel circuit including a drive transistor whose source is connected to the first power supply terminal and whose drain is connected to the display element, and wherein a periodic variation in a property of the drive transistor appears in a row which the pixels form.

According to a second aspect of the present invention, there is provided an array substrate comprising an insulating substrate, pixel circuits arrayed in a matrix form over the insulating substrate, and video signal lines arranged correspondently with columns which the pixel circuits form, wherein each of the pixel circuits comprises a thin film transistor whose source, drain and channel are formed in a polycrystalline semiconductor layer, the source being connected to a first power supply terminal, a capacitor connected between a constant potential terminal and a gate of the thin film transistor, an output control switch series connected with a display element between the drain and a second power supply terminal, a switch group which switches connections among the drain, the gate and the video signal line between a connected state in which the drain, the gate and the video signal line are connected to one another and a disconnected state in which the drain, the gate and the video signal line are disconnected from one another, and wherein a periodic variation in a property of the drive transistor appears in a row which the pixel circuits form.

According to a third aspect of the present invention, there is provided a method of manufacturing a display comprising a substrate, pixels arrayed in a matrix form over the substrate, and video signal lines arranged correspondently with columns which the pixels form, wherein each of the pixels comprises a display element and a pixel circuit including a drive transistor which includes a polycrystalline semiconductor layer and controls a magnitude of a signal to be supplied to the display element, comprising irradiating an amorphous semiconductor layer with a laser beam as a linear beam such that a longitudinal direction of a first irradiated position which is a position of the amorphous semiconductor layer simultaneously irradiated with the laser beam is parallel to each of the columns, and shifting the first irradiated position in a direction crossing the longitudinal direction of the first irradiated position to form the polycrystalline semiconductor layer.

According to a fourth aspect of the present invention, there is provided a method of manufacturing a display comprising a substrate, pixels arrayed in a matrix form over the substrate, and video signal lines arranged correspondently with columns which the pixels form, wherein each of the pixels comprises a display element and a pixel circuit including a drive transistor which includes a polycrystalline semiconductor layer and controls a magnitude of a signal to be supplied to the display element, comprising irradiating a semiconductor layer to be used as the polycrystalline semiconductor layer with an ion beam as a linear beam produced by using an extraction electrode provided with apertures which are arranged in a line at regular intervals such that a longitudinal direction of an irradiated position which is a position of the semiconductor layer simultaneously irradiated with the ion beam is perpendicular to each of the columns, and shifting the irradiated position in a direction crossing the longitudinal direction of the irradiated position.

According to a fifth aspect of the present invention, there is provided a display comprising a substrate, pixels arrayed in a matrix form over the substrate, and video signal lines arranged correspondently with columns which the pixels form, wherein each of the pixels comprises a display element arranged between first and second power supply terminals, and a pixel circuit including a drive transistor whose source is connected to the first power supply terminal and whose drain is connected to the display element, and wherein threshold voltages of the drive transistors periodically vary in a direction along the video signal line with a variation range of 10 mV or less.

### BRIEF DESCRIPTION OF DRAWINGS

FIG. 1 is a plan view schematically showing a display according to an embodiment of the present invention;

FIG. 2 is a sectional view showing an example of a structure which can be used for the display shown in FIG. 1;

FIG. 3 is a timing chart schematically showing an example of a method of driving the display shown in FIGS. 1 and 2;

FIG. 4 is a plan view schematically showing laser annealing carried out in manufacturing a display according to a first embodiment of the present invention;

FIG. 5 is a plan view schematically showing ion doping carried out in manufacturing a display according to a second embodiment of the present invention; and

FIG. 6 is a plan view schematically showing laser annealing and ion doping carried out in manufacturing a display according to a third embodiment of the present invention.

### BEST MODE FOR CARRYING OUT THE INVENTION

Several embodiments of the present invention will be described below in detail with reference to the accompanying drawings. The same reference numerals denote the same or similar constituent elements throughout the drawings, and a repetitive description thereof will be omitted.

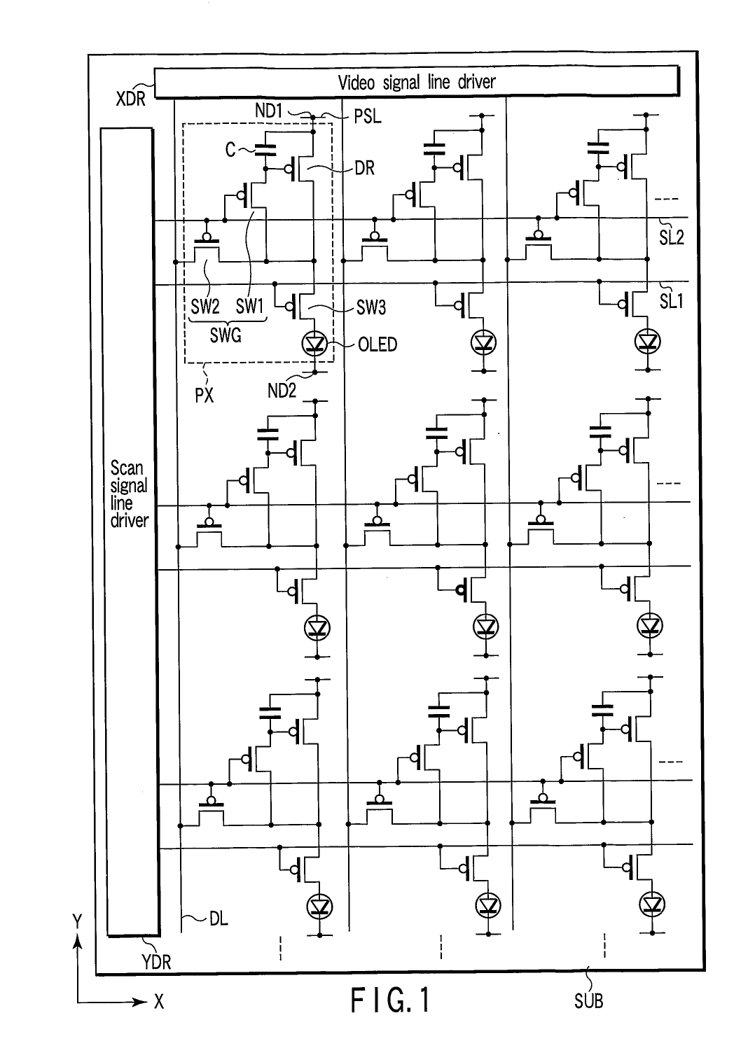

FIG. 1 is a plan view schematically showing a display according to an embodiment of the present invention.

The display is an active matrix display, for example, an active matrix organic EL display, and includes pixels PX. The pixels PX are arranged in a matrix form on an insulation substrate SUB such as a glass substrate.

A scan signal line driver YDR and a video signal line driver XDR are further arranged on the substrate SUB.

On the substrate SUB, scan signal lines SL1 and SL2 connected to the scan signal line driver YDR extend in a row direction of the pixels PX (X-direction). The scan signal line driver YDR supplies the scan signal lines SL1 and SL2 with scan signals as a voltage signal.

On the substrate SUB, video signal lines DL connected to the video signal line driver XDR also extend in a column direction of the pixels PX (Y-direction). The video signal line driver XDR supplies the video signal lines DL with a video signal.

Further, a power supply line PSL is arranged on the substrate SUB.

The pixel PX includes a drive control element DR, a first switch SW1, a second switch SW2, an output control switch SW3, a capacitor C, and a display element OLED. The switches SW1 and SW2 constitute a switch group SWG.

The display element OLED includes an anode and a cathode which face each other and an active layer whose optical behavior changes according to a current flowing through the anode and cathode. Here, as an example, the display element OLED is an organic EL element which includes an emitting layer as the active layer. In addition, as an example, it is assumed that the anode is a lower electrode, and that the cathode is an upper electrode facing the lower electrode with the active layer therebetween.

The drive control element DR is a thin film transistor (hereinafter, referred to as TFT) whose source, drain, and channel are formed in a polycrystalline semiconductor layer. Here, as an example, a p-channel TFT using a polycrystalline silicon layer as the polycrystalline semiconductor layer is utilized as the drive control element DR. The source of the drive control element DR is connected to a power supply line PSL, and the gate of the drive control element DR is connected to one electrode of the capacitor C. A node ND1 on the power supply line PSL corresponds to a first power supply terminal.

The switch group SWG switches a connection state among the drain of the drive control element DR, the gate of the drive control element DR, and the video signal line DL between a state in which they are connected to one another and a state in which they are disconnected from one another. The switch group SWG can use a variety of structures, which will be described later.

In this example, a switch group SWG is composed of two switches SW1 and SW2.

The switch SW1 has a terminal connected to the gate of the drive control element DR. The switch SW1 or an combination of the switches SW1 and SW2 switches a connection state between the drain and the gate of the drive control element DR between a state in which they are connected to each other and a state in which they are disconnected from each other.

The switch SW1 is connected between the gate and drain of the drive control element DR, for example. A switching operation of the switch SW1 is controlled by, for example, a scan signal which is transmitted from the scan signal line driver YDR via the scan signal line SL2. Here, as the switch SW1, used is the p-channel TFT which includes a gate connected to the scan signal line SL2, and source and drain connected to the gate and drain of the drive control element DR, respectively.

The switch SW2 has a terminal connected to the video signal line DL. The switch SW2 or the combination of the switches SW2 and SW1 switches a connection state between the drain of the drive control element DR and the video signal line DL between a state in which they are connected to each other and a state in which they are disconnected from each other.

The switch SW2 is connected between the drain of the drive control element DR and the video signal line DL, for example. A switching operation of the switch SW2 is controlled by, for example, a scan signal transmitted from the scan signal line driver YDR via the scan signal line SL2. Here, as the switch SW2, used is the p-channel TFT which includes a gate connected to the scan signal line SL2, and source and drain connected to the drain of the drive control element DR and the video signal line DL, respectively.

The output control switch SW3 and the display element OLED are connected in series between an output terminal of the drive control element DR and a second power supply element ND2. Here, as the switch SW3, used is a p-channel TFT which includes a gate connected to the scan signal line SL1, and source and drain connected to the drain of the drive control element DR and an anode of the display element OLED, respectively. In addition, it is assumed that an electric potential of the power supply terminal ND2 is set lower than that of the power supply terminal ND1. In this example, the output control switch SW3 and the display element OLED are connected in series in this order between the drain of the drive control element DR and the second power supply terminal ND2. The connection order may be reversed.

The capacitor C is connected between a constant potential terminal and the gate of the drive control element DR. Here, as an example, the capacitor C is connected between the node ND1 on the power supply line PSL and the gate of the drive control element DR. However, the constant potential terminal to which the capacitor C is connected may be electrically insulated from the power supply line PSL. That is, another constant potential terminal electrically insulated from the power supply line PSL may be utilized as the above described constant electrical potential terminal.

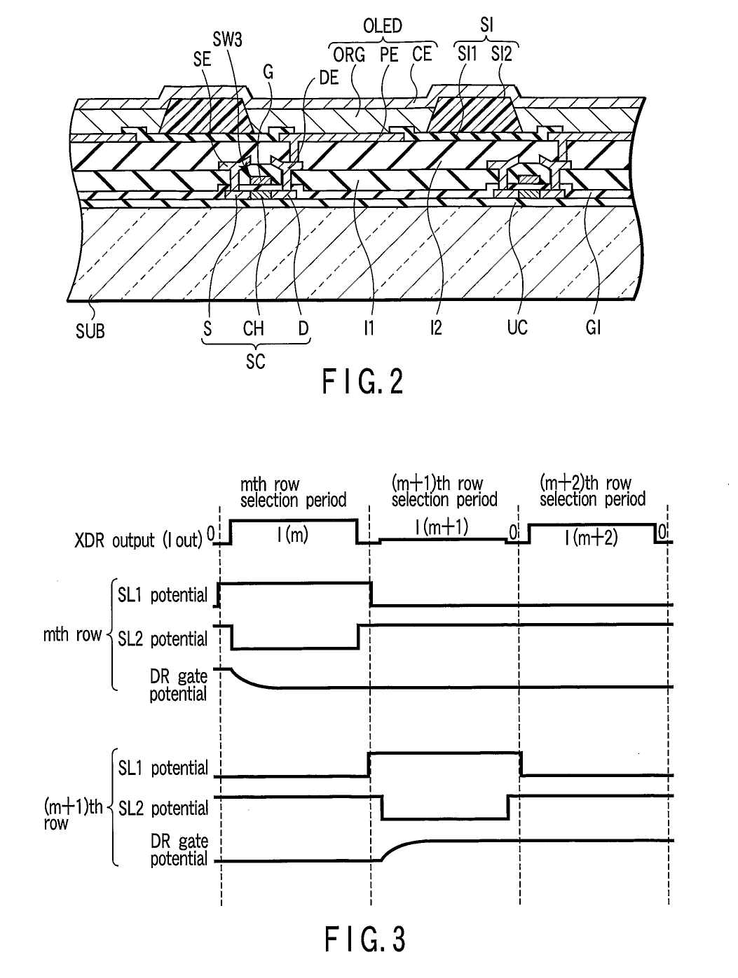

FIG. 2 is a partial cross section showing an example of a structure which can be used for the display shown in FIG. 1.

As shown in FIG. 2, an undercoat layer UC is arranged on a main surface of the insulation substrate SUB. As the undercoat layer UC, for example, a multilayer structure of a SiNx layer and a SiO₂ layer, or the like can be used.

On the undercoat layer UC, a patterned polycrystalline silicon layer is arranged as a polycrystalline semiconductor layer SC. The polycrystalline semiconductor layer SC can be formed by, for example, the following method.

First, an amorphous semiconductor layer is formed on the undercoat layer UC. The amorphous semiconductor layer can be formed by, for example, a plasma CVD (PECVD: plasma enhanced chemical vapor deposition). For example, the amorphous semiconductor layer can be formed by the plasma CVD using silane gas as row material gas.

Next, the amorphous semiconductor layer is subjected to a fusing and recrystallization process, and then patterned. For the fusing and recrystallization process, for example, a laser annealing using an excimer laser such as a XeCl excimer laser can be utilized. In addition, photolithography and etching can be utilized for patterning of the semiconductor layer. As described above, the crystalline semiconductor layers SC are obtained.

In each semiconductor layer SC, formed are source and drain D of the TFT which are spaced from each other. A region CH between the source S and drain D in the semiconductor layer SC is used as a channel.

The source S and drain D can be formed by carrying out ion doping with a gate G described later being used as a mask. An ion beam used in the ion doping may be a linear beam or may be a planar beam. In addition, impurity activation may be carried out at any stage after ion doing if necessary.

Prior to forming the gate G, in order to regulate a threshold voltage of the TFT, ion doping is carried out for the polycrystalline semiconductor layer. In this case, the ion doping is carried out by using a linear beam as an ion beam, for example. Further, ion doping for forming an LDD (lightly doped drain) structure may be carried out.

A gate insulator GI is formed on the semiconductor layer SC. On the gate insulator GI, a first conductor pattern and an insulation film I1 are sequentially formed. The first conductor pattern is utilized as the gate G of the TFT, a first electrode (not shown) of the capacitor C, the scan signal line SL, or a wire for connecting them. In addition, the insulation film I1 is utilized as an interlayer dielectric film and a dielectric layer of the capacitor C.

Although FIG. 2 depicts only the switch SW3 as a TFT, there can be used a structure similar to that of the switch SW3 for another TFT which is included in a pixel circuit, for example, the switches SW1 and SW2 or the drive control element DR, or alternatively, a TFT in the video signal driver XDR and in the scan signal line driver YDR as well.

A second conductor pattern is formed on the insulation film I1. The second conductor pattern is utilized as a source electrode SE, a drain electrode DE, a second electrode (not shown) of the capacitor C, the video signal line DL, the power supply line PSL, or a wire for connecting them. The source electrode SE and drain electrode DE are connected to the source S and drain D of the TFT via through holes formed in the insulation films GI and I1.

An insulation film I2 and a third conductor pattern are sequentially formed on the second conductor pattern and the insulation film I1. The insulation film I2 is utilized as a passivation film and/or a flattening layer. The third conductor pattern is utilized as a pixel electrode PE of each organic EL element OLED. Here, as an example, the pixel electrode PE is assumed to be an anode.

On the insulation film I2, a through hole communicating with the drain electrode DE connected to the drain D of the output control switch SW3 is provided for each pixel PX. Each pixel electrode PE covers a sidewall and a bottom of the through hole. In this manner, each pixel electrode is connected to the drain D of the output control switch SW3 via the drain electrode DE.

An insulating separator layer SI is formed on the insulation film I2. Here, as an example, although the insulating separator layer SI has a multilayer structure of an inorganic insulation layer SI1 and an organic insulation layer SI2, the inorganic insulation layer SI1 may be omitted.

In the insulating separator layer SI, a through hole is formed at a position of the pixel electrode PE. In the through hole of the insulating separator layer SI, an organic layer ORG including an emitting layer is deposited on the pixel electrode PE. The emitting layer is, for example, a thin film including a luminescent organic compound which emits light of red, green or blue. The organic layer ORG can further include, for example, a hole injection layer, a hole transporting layer, an electron injection layer, an electron transporting layer and the like, in addition to the organic emitting layer. Each of the layers included in the organic layer ORG can be formed by, for example, a mask evaporating technique or an inkjet technique.

A common electrode CE is arranged on the insulating separator layer SI and the organic layer ORG. The common electrode CE is electrically connected to an electrode wire, which serves as the node ND2, via contact holes (not shown) formed in the insulation film I1, the insulation film I2, and the insulating separator layer SI. Here, as an example, the common electrode CE is assumed to be a cathode.

Each organic EL element OLED is composed of the pixel electrode PE, organic layer ORG, and common electrode CE.

In this display, the substrate SUB, the pixel electrode PE, members interposed between them, and the insulating separator layer SI constitute an array substrate. As shown in FIG. 1, the array substrate can further include the scan signal line driver YDR and the video signal line driver XDR, etc.

FIG. 3 is a timing chart schematically showing an example of a method of driving the display shown in FIGS. 1 and 2.

In FIG. 3, the abscissa represents a time, and the coordinate represents an electric potential or a magnitude of current. Further, in FIG. 3, the waveform denoted by “XDR output (Iout)” represents a current which the video signal line driver XDR makes flow through the video signal line DL, the waveforms denoted by “SL1 electric potential” and “SL2 electric potential” represent electric potentials of scan signal lines SL1 and SL2, respectively, and the waveform denoted by “DR gate potential” represents a gate potential of the drive control element DR.

According to the method of FIG. 3, the display shown in FIGS. 1 and 2 is driven by the following method.

In the case of displaying some gray level on an mth pixel PX, during a period of selecting the mth pixel PX, i.e., the mth row selection period, for example, the electric potential of the scan signal line SL1 is first changed from a second electric potential which makes the switch SW3 ON state to a first electric potential which makes the switch SW3 OFF state, thereby opening the switch SW3 (non-conducting state). The following write operation is carried out during a write period in which the switch SW3 is opened.

That is, for example, the electric potential of the scan signal line SL2 is changed from a third electric potential which makes the switches SW1 and SW2 OFF state to a fourth electric potential which makes the switches SW1 and SW2 ON state, thereby closing the switches SW1 and SW2 (conducting state). In this manner, the gate of the drive control element DR, the drain of the drive control element DR, and the video signal line DL are connected to one another.

In this state, the video signal line driver XDR supplies the selected pixel PX with a video signal via the video signal line DL. That is, by means of the video signal driver XDR, a current Iout is made flow from the power supply terminal ND1 to the video signal line DL. The magnitude of the current Iout corresponds to the magnitude of a drive current flowing through the display element OLED of the selected pixel PX, i.e., a gray level to be displayed on the selected pixel PX. By carrying out this write operation, the gate potential of the drive control element DR is set at a value when the current Iout flows between the source and the drain.

Next, for example, the electric potential of the scan signal line SL2 is changed from the fourth electric potential to the third electric potential, thereby opening the switches SW1 and SW2 (non-conducting state). That is, the gate of the drive control element DR, the drain of the drive control element DR, and the video signal line DL are disconnected from one another. Then, in this state, the electric potential of the scan signal line SL1 is changed from the first electric potential to the second electric potential, thereby closing the output control switch SW3 (conducting state).

As described above, by the write operation, the gate potential of the drive control element DR is set at a value which makes the current Iout flow. The gate potential is maintained until the switches SW1 and SW2 are closed. Therefore, during an effective display period in which the switch SW3 is closed, a drive current whose magnitude corresponds to that of the current Iout flows through the display element OLED. The display element OLED displays a gray level which corresponds to the magnitude of the drive current.

As has been described above, in the case where the display according to a prior art is driven by the driving method of FIG. 3, there is a possibility that streaks parallel to the scan signal lines SL1 and SL2 appear at regular intervals in a direction along the video signal line DL. As a result of investigating the cause of such streaks, the present inventor has found out that, among rows and columns which the pixels form, the properties of the drive control element DR, in particular, threshold voltages periodically vary in the column which the pixels PX form. This is described in detail below.

For example, consider a case in which the same gray level is displayed on a pixel PX in mth row and a pixel PX in (m+1)th row which are connected to the same video signal line DL. In this case, an output current Iout of the video signal line driver XDR during a write period for the pixel PX in mth row is equal to an output current Iout of the video signal line driver XDR during a write period for the pixel PX in (m+1)th row.

In the method of FIG. 3, immediately after the end of the write period for the pixel PX in mth row, the gate potential of the drive control element DR included in that pixel PX is expected to be set at a value Vg(m) which makes the current Iout flow between the source and drain of the drive control element DR. Similarly, immediately after the end of the write period for the pixel PX in (m+1)th row, the gate potential of the drive control element DR included in that pixel PX is expected to be set at a value Vg(m+1) which makes the current Iout flow between the source and drain of the drive control element DR.

However, in the case where the current Iout is small, if the pixel in the mth row and the pixel in the (m+1)th row are different from each other in the threshold voltage Vth of the drive control element DR, the gate potential of the drive control element DR included in the pixel PX in (m+1)th row cannot be precisely set at Vg(m+1) during the write period due to the influence of the parasitic capacitance of the video signal line DL. As a result, the pixel PX in mth row and the pixel PX in (m+1)th row are different from each other in a magnitude of the drive current.

According to the investigation of the present inventor, in a display in which a streak-like display unevenness occurs, although the adjacent pixels PX in each row are substantially equal to each other in properties of the drive control element DR, i.e., the threshold voltage Vth and the mobility, the adjacent pixels PX in each column periodically vary in the threshold voltage Vth of the drive control element DR or both of the threshold voltage Vth and the mobility. This is because the streaks parallel to the scan signal lines SL1 and SL2 appear on a display image at regular intervals in a direction along the video signal line DL.

The present inventor further investigated the reason for the periodic variance in threshold voltage Vth of the drive control element DR or in both of the threshold voltage Vth and the mobility. As a result, the present inventor has found out that, in the case of forming the polycrystalline semiconductor layer SC of the drive control element DR by laser annealing the amorphous semiconductor layer, a periodic variance occurs with the threshold voltage Vth and the mobility of the drive control element DR.

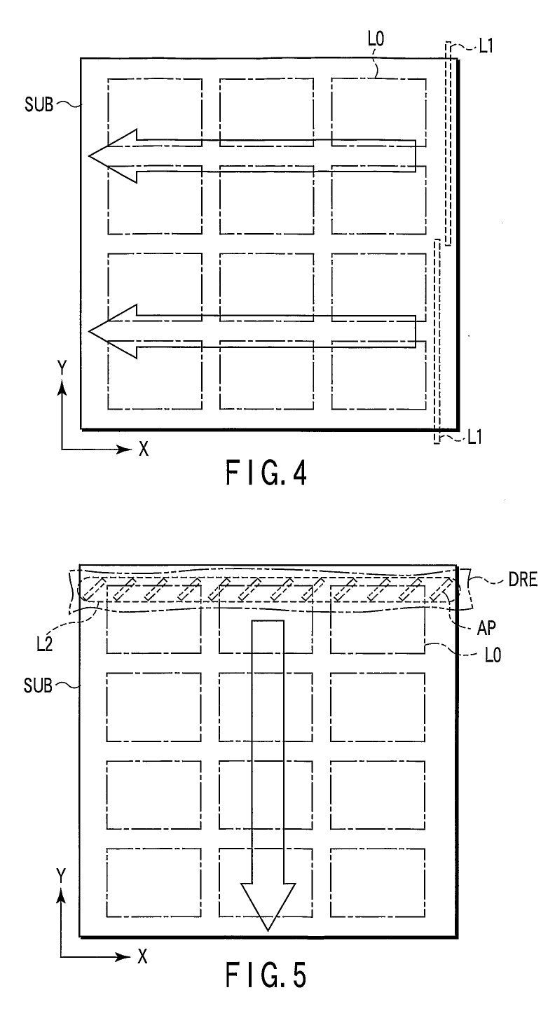

FIG. 4 is a plan view schematically showing laser annealing carried out in manufacturing the display according to a first embodiment of the present invention.

FIG. 4 depicts an insulation substrate SUB with semiconductor layer before broken into individual displays. In FIG. 4, the alternate long and short dash line L0 represents a part of a scribe line. That is, a portion of the insulation substrate SUB shown in FIG. 4 which is surrounded by the alternate long and short dash line L0 is utilized for the display.

In FIG. 4, of a main surface of the substrate SUB on which the semiconductor layer SC is formed, the area surrounded by the dashed line L1 represents an area which is simultaneously irradiated with a laser beam as a linear beam.

The term “linear beam” used here means an energy beam capable of simultaneously irradiating a straight line-shaped or band-shaped region in a plane when radiating the energy beam from a direction substantially perpendicular to the plane, as generally used.

In this embodiment, during laser annealing, as shown in FIG. 4, a longitudinal direction of the area surrounded by the dashed line L1 and Y-direction, i.e., a direction of the column which the pixels PX form, are equal to each other. Further, the area L1 irradiated with a laser beam as a linear beam is moved in a direction crossing the Y-direction, for example, in X-direction (a direction of row which the pixels PX form). Typically, the location of the linear beam is fixed in an annealing device, and the substrate SUB on a stage continuously moves with respect to the linear beam.

In the meantime, irradiation of each amorphous semiconductor layer with a laser beam is carried out during a period in which a relative speed of a laser beam with respect to the substrate SUB, i.e. a scan speed is stable. However, it is extremely difficult to maintain the power of the laser beam to be always constant. In general, the laser beam power periodically fluctuates. Thus, a laser beam exposure has a periodic distribution along a moving direction of the area L1, i.e., the scan direction.

A laser beam exposure of the amorphous semiconductor layer influences a crystal grain size of the polycrystalline semiconductor layer SC or the number of crystal defects at the grain boundaries. In addition, the threshold voltage or mobility of the drive control element DR depends on the crystal grain size or the number of crystal defects. Therefore, in the case where a laser beam exposure has a periodic distribution along the scan direction, the threshold voltage or mobility of the drive control element DR periodically varies along the scan direction correspondently with the periodic distribution of the exposure.

Thus, unlike the method shown in FIG. 4, when the longitudinal direction of the area L1 and X-direction are aligned with each other and when the scan direction is defined as the Y-direction, the threshold voltage or mobility of the drive control element DR periodically varies along the Y-direction, i.e., the column direction of the pixel PX. In other words, the threshold voltage or mobility of the drive control element DR periodically varies along the video signal line DL. As a result, due to the influence of the parasitic capacitance of the video signal line DL, the streaks parallel to the scan signal lines SL1 and SL2 appear on a display image at regular intervals in a direction along the video signal line DL.

In contrast, when the method shown in FIG. 4 is used, a periodic variance in threshold voltage or mobility caused by a periodic fluctuation of laser beam power does not appear in a direction along the video signal line DL. Further, in the area L1, a power distribution of a laser beam in the longitudinal direction of the area L1 is extremely small. Therefore, when the method shown in FIG. 4 is used, it is possible to prevent the streaks parallel to the scan signal lines SL1 and SL2 from appearing on a display image at regular intervals in a direction along the video signal line DL.

When the method shown in FIG. 4 is used, a periodic variance in threshold voltage or mobility caused by a periodic fluctuation of laser beam power appears in a direction along the scan signal lines SL1 and SL2. The streak-shaped display unevenness is caused by the fact that the threshold voltages of the drive control element DR are greatly different from each other between the adjacent pixels PX along the video signal line DL. Thus, by using the method shown in FIG. 4, it is not possible for the streaks parallel to the video signal line DL to periodically appear on a display image in a direction along the scan signal lines SL1 and SL2.

Next, a second embodiment of the present invention will be described.

As described previously, in order to regulate a threshold voltage of the TFT, ion doping is carried out for the polycrystalline semiconductor layer SC. However, in accordance with this process as well, a periodic variance in threshold voltage occurs. In particular, this variance occurs in the case where the following method is used.

Ion doping is carried out by ionizing a doping gas such as, for example, B₂H₆ or PH₃, by a plasma discharge, and applying a voltage to an extraction electrode to accelerate and implant the ions into the polycrystalline semiconductor layer SC. The ion beam may be either a planar beam and a linear beam. In the case where dimensions of the substrate SUB are comparatively large, in general, a linear beam is produced as an ion beam by using an extraction electrode which is provided with apertures arranged in a line at regular intervals, and an irradiated position is shifted in a direction crossing a longitudinal direction of an irradiated area which is an area irradiated with an ion beam to carry out ion doping. In this embodiment, a streak-shaped display unevenness caused by carrying out such an ion doping is prevented from occurring.

FIG. 5 is a plan view schematically showing ion doping carried out in manufacturing the display according to the second embodiment of the present invention.

In FIG. 5, of a main surface of the substrate SUB on which the semiconductor layer SC is formed, the area surrounded by the dashed line L2 represents an area which is simultaneously irradiated with an ion beam as a linear beam at a point of time. Further, in FIG. 5, reference symbol DRE denotes an extraction electrode of an ion doping apparatus, and reference symbol AP denotes an aperture of the extraction electrode DRE.

In the method of FIG. 5, the longitudinal direction and X-direction of an area L2 are equal to each other, and the scan direction is a direction crossing an X-direction, for example, a Y-direction. In this manner, ion beam irradiation is carried out for each row of the pixel PX.

In the meantime, irradiation of each semiconductor layer with an ion beam is carried out during a period in which a relative moving speed of ion beams with respect to the substrate SUB, i.e., a scan speed is stable. However, in the case where the extraction electrode DRE shown in FIG. 5 is used, in the area L2, a species density has a periodic distribution along the longitudinal direction of the area L2. Thus, the concentration of the impurities in the polycrystalline semiconductor layer SC periodically varies along the longitudinal direction of the area L2.

A threshold voltage of the drive control element DR depends on the concentration of impurities in the polycrystalline semiconductor layer SC, in particular, on the concentration of impurities in a region CH. Therefore, in the case where the concentration of impurities in the polycrystalline semiconductor layer SC has a periodic distribution along the longitudinal direction of the area L2, the threshold voltage of the drive control element DR periodically varies along the longitudinal direction of the area L2 correspondently with a periodic distribution of the concentration of impurities.

Thus, unlike the method shown in FIG. 5, when the longitudinal direction of the area L2 and Y-direction are aligned with each other and when the scan direction is defined as the X-direction, the threshold voltage of the drive control element DR periodically varies along the Y-direction, i.e., in the column direction of the pixel PX. In other words, the threshold voltage of the drive control element DR periodically varies along the video signal line DL. As a result, due to the influence of the parasitic capacitance of the video signal line DL, the streaks parallel to the scan signal lines SL1 and SL2 appear on a display image at regular intervals in a direction along the video signal line DL.

In contrast, when the method shown in FIG. 5 is used, a periodic variance in threshold value caused by a periodic distribution of ion species density does not appear in a direction along the video signal line DL. Therefore, when the method shown in FIG. 5 is used, it is possible to prevent the streaks parallel to the scan signal lines SL1 and SL2 from appearing on a display image at regular intervals in a direction along the video signal line DL.

When the method shown in FIG. 5 is used, a periodic variance in threshold voltage caused by a periodic distribution of ion species density appears in a direction along the scan signal lines SL1 and SL2. The streak-shaped display unevenness is caused by the fact that the threshold voltages of the drive control elements DR are greatly different from each other between the adjacent pixels PX along the video signal line DL. Thus, by using the method shown in FIG. 5, it is not possible for the streaks parallel to the video signal line DL to periodically appear on a display image in a direction along the scan signal lines SL1 and SL2.

Note that ion doping for a region CH may be carried out before laser annealing. Alternatively, ion doping for a region CH may be carried out after laser annealing.

Next, a third embodiment of the present invention will be described.

In the third embodiment, the polycrystalline semiconductor layer SC is formed by laser annealing the amorphous semiconductor layer. In addition, the polycrystalline semiconductor layer SC, in particular, a region CH is subjected to an ion doping which uses an ion beam described in the second embodiment.

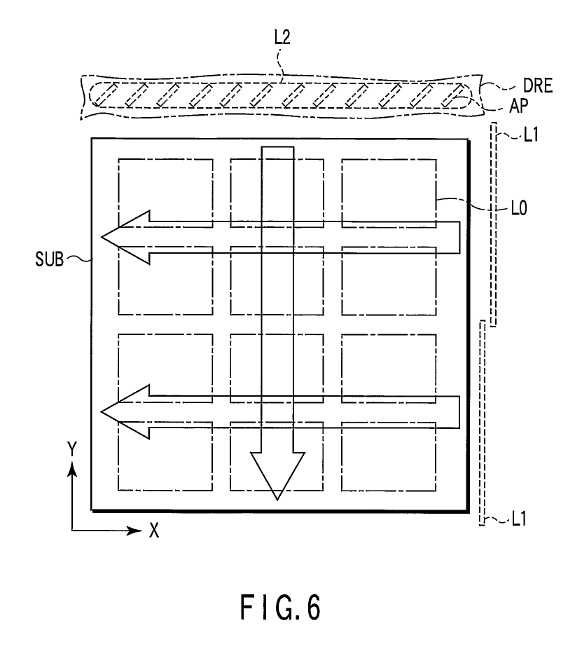

FIG. 6 is a plan view schematically showing laser annealing and ion doping carried out in manufacturing a display according to the third embodiment of the present invention.

In the method of FIG. 6, the longitudinal direction of the area L1 and Y-direction are equal to each other. In addition, the scan direction of laser beams is a direction crossing the Y-direction, for example, the X-direction. In this manner, laser beam irradiation is carried out for each column of the pixel PX.

Further, in the method of FIG. 6, the longitudinal direction of the area L2 and X-direction are equal to each other. In addition, the scan direction of ion beams is a direction crossing the X-direction, for example, the Y-direction. In this manner, ion beam irradiation is carried out for each row of the pixel PX.

By doing this, a periodic variance in threshold voltage or mobility caused by a periodic fluctuation of laser beam power does not appear in a direction along the video signal line DL. In addition, a periodic variance in threshold value caused by a periodic distribution of ion species density also does not appear in a direction along the video signal line DL. Therefore, when the method shown in FIG. 6 is used, it is possible to prevent the streaks parallel to the scan signal lines SL1 and SL2 from appearing on a display image at regular intervals in a direction along the video signal line DL.

When the method shown in FIG. 6 is used, a periodic variation in threshold voltage or mobility caused by a periodic fluctuation of laser beam power appears in a direction along the scan signal lines SL1 and SL2. Further, when the method shown in FIG. 6 is used, a periodic variance in threshold voltage caused by a periodic distribution of ion species density appears in a direction along the scan signal lines SL1 and SL2. Therefore, in the direction along the scan signal lines SL1 and SL2, there appears a superposition of the periodic variance in threshold voltage caused by the periodic fluctuation of laser beam power and the periodic variance in threshold voltage caused by the periodic distribution of ion species density.

In the above embodiment a laser annealing process and an ion doping process are described as example of the present invention. However, the present invention can be applied to another process which may produce a periodic unevenness in the TFT properties. Namely, if a distribution direction of periodic unevenness and a wiring direction of a video signal line DL are made orthogonal to each other, it becomes possible to reduce a load on an operation for canceling the variance of TFT properties. In addition, it becomes possible to achieve an active matrix display which is excellent in grayscale reproducibility within a lower gray level range and in which luminance unevenness is suppressed.

A periodic threshold voltage variation of drive control element DR in a direction along the video signal line is desirably within a range of 10 mV or less, and more desirably within a range of 5 mV or less. In the case where a periodic fluctuation in a certain process which causes a periodic unevenness in TFT properties is within a range corresponding to a threshold variation of 10 mV or less, luminance unevenness can be effectively suppressed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A display comprising:
a substrate;
pixels arrayed in a matrix form over the substrate; and
video signal lines arranged correspondently with columns which the pixels form,
wherein each of the pixels comprises a display element arranged between first and second power supply terminals, and a pixel circuit including a drive transistor whose source is connected to the first power supply terminal and whose drain is connected to the display element, and
wherein a periodic variation in a property of the drive transistor appears in a row which the pixels form.

2. The display according to claim 1, wherein the drive transistor is a thin film transistor which comprises a polysilicon layer.

3. The display according to claim 1, wherein the display element is an organic EL element.

4. The display according to claim 3, wherein the display is a current drive type display in which a current signal is written as a video signal in the drive transistor.

5. An array substrate comprising:
an insulating substrate;
pixel circuits arrayed in a matrix form over the insulating substrate; and
video signal lines arranged correspondently with columns which the pixel circuits form,
wherein each of the pixel circuits comprises a thin film transistor whose source, drain and channel are formed in a polycrystalline semiconductor layer, the source being connected to a first power supply terminal, a capacitor connected between a constant potential terminal and a gate of the thin film transistor, an output control switch series connected with a display element between the drain and a second power supply terminal, a switch group which switches connections among the drain, the gate and the video signal line between a connected state in which the drain, the gate and the video signal line are connected to one another and a disconnected state in which the drain, the gate and the video signal line are disconnected from one another, and
wherein a periodic variation in a property of the drive transistor appears in a row which the pixel circuits form.

6. A method of manufacturing a display comprising a substrate, pixels arrayed in a matrix form over the substrate, and video signal lines arranged correspondently with columns which the pixels form, wherein each of the pixels comprises a display element and a pixel circuit including a drive transistor which includes a polycrystalline semiconductor layer and controls a magnitude of a signal to be supplied to the display element, comprising:
irradiating an amorphous semiconductor layer with a laser beam as a linear beam such that a longitudinal direction of a first irradiated position which is a position of the amorphous semiconductor layer simultaneously irradiated with the laser beam is parallel to each of the columns, and shifting the first irradiated position in a direction crossing the longitudinal direction of the first irradiated position to form the polycrystalline semiconductor layer.

7. The method according to claim 6, further comprising:
irradiating the semiconductor layer with an ion beam as a linear beam produced by using an extraction electrode provided with apertures which are arranged in a line at regular intervals such that a longitudinal direction of a second irradiated position which is a position of the semiconductor layer simultaneously irradiated with the ion beam is parallel to each of rows which the pixels form, and shifting the second irradiated position in a direction crossing the longitudinal direction of the second irradiated position.

8. A method of manufacturing a display comprising a substrate, pixels arrayed in a matrix form over the substrate, and video signal lines arranged correspondently with columns which the pixels form, wherein each of the pixels comprises a display element and a pixel circuit including a drive transistor which includes a polycrystalline semiconductor layer and controls a magnitude of a signal to be supplied to the display element, comprising:
irradiating a semiconductor layer to be used as the polycrystalline semiconductor layer with an ion beam as a linear beam produced by using an extraction electrode provided with apertures which are arranged in a line at regular intervals such that a longitudinal direction of an irradiated position which is a position of the semiconductor layer simultaneously irradiated with the ion beam is perpendicular to each of the columns, and shifting the irradiated position in a direction crossing the longitudinal direction of the irradiated position.

9. The method according to claim 7 or 8, wherein a portion of the semiconductor layer to be used as a channel is irradiated with the ion beam.

10. The method according to claim 6 or 8, wherein the polycrystalline semiconductor layer is a polysilicon layer.

11. The method according to claim 8, wherein the semiconductor layer before irradiated with the ion beam is an amorphous silicon layer.

12. The method according to claim 8, wherein the semiconductor layer before irradiated with the ion beam is a polycrystalline silicon layer.

13. The method according to claim 6 or 8, wherein the display element is an organic EL element.

14. A display comprising:
a substrate;
pixels arrayed in a matrix form over the substrate; and
video signal lines arranged correspondently with columns which the pixels form,
wherein each of the pixels comprises a display element arranged between first and second power supply terminals, and a pixel circuit including a drive transistor whose source is connected to the first power supply terminal and whose drain is connected to the display element, and
wherein threshold voltages of the drive transistors periodically vary in a direction along the video signal line with a variation range of 10 mV or less.
